(19) United States
(12) Patent Application Publication
(10) Pub. No.: US 2018/0240671 A1
(43) Pub. Date: Aug. 23, 2018

(54) LIQUID PHASE EPITAXY DOPING AND SILICON PN JUNCTION PHOTOVOLTAIC DEVICES

(71) Applicant: The Regents of the University of California, Oakland, CA (US)

(72) Inventors: David Fenning, La Jolla, CA (US); Ernesto Magana, La Jolla, CA (US)

(21) Appl. No.: 15/901,363

(22) Filed: Feb. 21, 2018

Related U.S. Application Data
(60) Provisional application No. 62/462,611, filed on Feb. 23, 2017.

(51) Int. Cl. H01L 21/228; H01L 31/065; H01L 31/18; H01L 21/02

(52) U.S. Cl. CPC H01L 21/228; H01L 21/02057; H01L 31/1804; H01L 31/065

(57) ABSTRACT

A method for forming a doped silicon layer or a silicon alloy includes providing a silicon substrate having a silicon surface. An eutectic-former layer with dopant is formed on the silicon surface. Heating is conducted past a system eutectic temperature of the eutectic-former layer and silicon to form a liquid eutectic melt that incorporates some of the silicon near-surface into the liquid eutectic melt. Cooling to supersaturate the liquid eutectic melt with silicon and recrystallize silicon doped with the dopant. A silicon solar cell includes an emitter layer within a silicon substrate. A p-n junction is defined by a junction of the emitter layer with the remaining silicon substrate. The emitter has a doping profile with a doping concentration at the p-n junction that is equal or greater than the doping concentration at a surface of the emitter layer.

### PRIORITY CLAIM AND REFERENCE TO RELATED APPLICATION

The application claims priority under 35 U.S.C. § 119 from prior provisional application Ser. No. 62/462,611, which was filed Feb. 23, 2017.

### FIELD

Fields of the invention include semiconductor fabrication methods and optoelectronic devices. Example applications of the invention include forming p-n junctions and silicon photovoltaic devices, such as solar cells. Additional applications of the invention include the formation of doped layers and junctions in a variety of semiconductor devices, including, for example, applications such as—mobile power-generation applications, distributed generation systems, and central power production. Methods of the invention can also form silicon alloys. Another example application is in energy storage, where doped silicon alloys of the invention can provide for next-generation Li-ion battery anodes.

### BACKGROUND

The best commercial solar cells suffer from poor efficiency, meaning that a small portion of the incident energy is converted to electrical energy. It is a goal of research to provide solar cells that are more efficient, such that the installation and use of solar panels becomes commercially viable without subsidies. One of the problems in current state-of-the-art silicon solar cells is the recombination of carriers in the emitter region of the solar cell (thin doped layer that receives solar energy), which prevents the carriers from contributing to the electrical energy generated by the solar cell. Such recombination of carriers in the emitter limits the potential efficiency of next generation state-of-the art solar cells to about 22.5% efficiency. Very expensive techniques with limited application for mass manufacture have pushed the efficiency to 25.8%. Cuevas and Russell found a 26.2% efficiency limit for silicon solar cells with a nearly perfect silicon absorber when co-optimizing a metallization grid and the emitter. A. Cuevas et al., “Co-optimisation of the emitter region and the metal grid of silicon solar cells,” Prog. Photovoltaics Res. Appl. 8, 603 (2000). The optimum emitter was 2-3 μm thick and 80-100 Ohm/sq. with a surface concentration of 4-6·10¹⁸ cm. Such an emitter would be nearly impossible to produce by prior P-diffusion techniques.

The present inventors have identified a primary factor contributing to this loss, which is the inflexible constraints of solid-state diffusion kinetics during emitter formation in a typical POCl₃ process used to form the doped emitter layer. POCl₃ is a gaseous precursor that in the state-of-the-art solar cell formation processes forms a phosphosilicate glass (SiO₂ with P) on the front surface of the wafer during a chemical vapor deposition process at high temperature >800° C., which layer is then used for solid-state diffusion. The solid-state diffusion provides high concentrations of inactive phosphorus and a heavily-doped, difficult-to-passivate front surface.

Solid state diffusion or gas diffusion processes from gas sources, liquid sources (such as phosphoric acid) or solid sources also limit throughput and raise manufacturing costs for solar cells. P-n junction formation by such conventional diffusion processes is a critical step in the manufacture of current silicon solar cells and require the largest thermal budget during the solar cell manufacturing process. The high temperatures—800-950° C. is typical—of today's phosphorus or boron chemical vapor deposition processes can seriously degrade high-quality silicon wafers through the in-diffusion of metal impurities from the furnace environment at even single parts per billion concentration. Furthermore, process cost is directly correlated with temperature, and throughput is limited by furnace heating and cooling.

One reason that the state-of-the-art solar cells have efficiency limited by the solid state or gas diffusion processes is that those prior diffusion process provide shallow, non-uniform doping profiles, and fail to provide an abrupt junction to the undoped region. Some recent efforts have focused on attempting to create deep abrupt junctions. Deep abrupt junctions have been explored by incremental improvements to solid-solid state diffusion or through built-in emitters using grown-in doping via direct epitaxy [R. Hao et al., “Kerfless epitaxial mono crystalline Si wafers with built-in junction and from reused substrates for high-efficiency PERx cells,” in IEEE Journal of Photovoltaics, vol. 6, no. 6, pp. 1451-1455, November 2016] yielding low sheet resistance emitters, lowering series resistance loss and producing higher FF [V. Mertens, S. Bordihn, A. Mohr, K. Petter, J. W. Müller, D. J. W. Jeong, R. Hao, T. Ravi, “21.4% Efficient fully screen printed n-type solar cell on epitaxially grown silicon wafers with built-in boron rear side emitter,” in 31st European Photovoltaic Solar Energy Conference and Exhibition, vol. 4, no. 1, pp. 1000-1002, 2015]. By reducing the surface recombination, >0.5 mA/cm² of photocurrent can be collected [B. Min et. al, “Incremental Efficiency Improvements of Mass-Produced PERC Cells up to 24%,” in Proc. 31st EU PVSEC, Hamburg, Germany, 2DO3.3 (2015)] producing more than a 15 mV gain in VOC [M. Rüdiger et al., “Numerical current density loss analysis of industrially relevant crystalline silicon solar cell concepts,” IEEE J Photovolt, 4, 533 (2014)], as surface dopant concentration and passivation are nearly perfectly correlated [B. Min et al., “Heavily doped Si:P emitters of crystalline Si solar cells: recombination due to phosphorus precipitation,” Phys. Status Solidi—Rapid Res. Lett. 8, 680 (2014)]. The incremental improvements have not provided significantly better efficiencies (predicted maximum of up to 24%) or commercially practical fabrication methods. The direct epitaxy of Hao et al. and Mertens et al. is also not presently suitable for large scale fabrication because it is slow in terms of growth rate (slow batches, though this is an area of research) and throughput (few wafers per batch), and expensive. It is also difficult to create junctions where dopants are incorporated of different types (p vs n). When a wafer is bulk doped with one type, a similarly doped layer can be formed for a back or front surface field but not for a junction—because depending on the method, the growth chamber will often be cross-contaminated, which does not allow control of doping. Hao et al have demonstrated the fabrication commercially under the company name CrystalSolar.

Liquid phase epitaxy has been investigated for back-surface field formation using the Al—Si system and low-temperature crystal growth for many years [P. Lolgen, C. Leguijt, J. A. Eikelboom, R. A. Steeman, vW. C. Sinke, L. A. Verhoef, P. F. A. Alkemade, E. Algra, “Aluminum back surface field doping profiles with surface recombination velocities below 200 cm/s.,” IEEE Photovoltaics Specialists Conference, vol. 23, pp. 236-242, 1993; M. G. Mauk, Silicon, Germanium and Silicon-Germanium Liquid Phase Epitaxy (2007)]. Recent work has reinforced the value of boron-doping the aluminum source for back-surface field formation [M. Rauer, C. Schmiga, M. Glatthaar, and S. W. Glunz, “Alloying from Screen-Printed Aluminum Pastes Containing Boron Additives. IEEE J. Photovoltaics 3, 206 (2013)], to enhance the field effect passivation.

The formation of back contacts via liquid phase epitaxy typically utilizes thick Al (sometimes with Boron additive) as the eutectic former/contact material. Typical thickness is between 3-6 μm, which prevents dewetting during the liquid phase epitaxy and provides sufficient metal to form the back contact. The silicon wafers used for the solar cells are typically P-type, and the back contact formation via liquid phase epitaxy creates a heavily P-type doped layer that interfaces with the back contact. Known liquid phase back contact epitaxy processes screen print a metal layers 10s of microns thick, anneal in the temperature range of about 700-800° C. for a very short time, and then cool to reconstitute the contact and the heavily P-type doped layer.

### SUMMARY OF THE INVENTION

An embodiment of the invention is a method for forming a doped silicon layer or a silicon alloy that includes providing a silicon substrate having a silicon surface. An eutectic-former layer with dopant is formed on the silicon surface. Heating is conducted past a system eutectic temperature of the eutectic-former layer and silicon to form a liquid eutectic melt that incorporates some of the silicon near-surface into the liquid eutectic melt. Cooling to supersaturate the liquid eutectic melt with silicon and recrystallize silicon doped with the dopant. Further cooling can be conducted to solidify remaining liquid eutectic melt. Dewetting prevention is preferably used, for example, with a capping layer, to prevent dewetting of the eutectic former. For P-type emitters, preferred eutectic formers include Sn, Zn and Al, and dopants include B, Ga, and Al, e.g. combinations of preferred P type dopant-metal eutectic formers include B—Sn, Ga—Sn, B—Zn, Ga—Zn, Al—Zn, and B—Al. For N type emitters, preferred eutectic formers include Sn, Zn, Bi and dopants include P and Sb, e.g., combinations of preferred N type dopant-metal eutectic formers include P—Sn, Sb—Zn, P—Zn, P—Al and P—Bi. Generally, the eutectic-former should have a low silicon eutectic temperature (e.g., <650°, more preferably <600°) and preferably a lower solubility in silicon compared to the dopant included in the material.

A preferred silicon solar cell includes an emitter layer within a silicon substrate. A p-n junction is defined by a junction of the emitter layer with the remaining silicon substrate. The emitter has a doping profile with a doping concentration at the p-n junction that is equal or greater than the doping concentration at a surface of the emitter layer. The p-n junction can be 100 nm to tens of microns deep. The dopant concentration at the p-n junction preferably transitions from a maximum doping concentration at the p-n junction to a background doping concentration within 1-100 nm of depth

A preferred method for forming a doped silicon layer or a silicon alloy includes providing a silicon substrate having a silicon surface. An eutectic-former Al layer is deposited on the silicon surface. The Al layer is capped for dewetting prevention The system is heated beyond the eutectic temperature of the eutectic-former layer and silicon to form a liquid eutectic melt that incorporates some of the silicon near-surface into the liquid eutectic melt. Cooling is conducted to supersaturate the liquid eutectic melt with silicon and recrystallize silicon doped with Al dopant.

### BRIEF DESCRIPTION OF THE DRAWINGS

FIGS. 1A-1C illustrate a preferred embodiment method for liquid phase doping of silicon in accordance with the invention;

FIGS. 2A and 2B respectively illustrate a comparison of the prior POCl₃ solid-state diffusion time/thermal budget compared to a preferred liquid phase doping of the invention and the modeled concentration versus depth profile of the prior POCl₃ solid-state diffusion compared to engineered and abrupt doping profiles produced by the preferred liquid phase doping of the invention;

FIG. 3A compares the performance potential of liquid phases doped emitters of the invention compared to POCl₃ and BBr₃ doped emitters; FIGS. 3B and 3C respectively for P-type and N-type emitters model the concentration versus depth profile of prior POCl₃ and BBr₃ doped emitters to abrupt doping profiles produced by the preferred liquid phase doping of the invention;

FIG. 4 compares sheet resistance as a function of annealing temperature for experimental devices to theoretical calculated values;

FIG. 5 is an SEM image of a 2 μm textured silicon surface after the formation of an experimental Al—B doped liquid phase epitaxy emitter of 4.9 μm depth in accordance with the preferred methods of the invention.

### DETAILED DESCRIPTION OF THE PREFERRED EMBODIMENTS

Preferred embodiments of the invention provide a transformative change in cell processing and p-n junction formation with value-added electronic properties of emitters formed via liquid phase epitaxy doping (LPE-D), and provide improved silicon solar cells. Preferred methods for forming p-n junctions in silicon solar cells provide improved electronic properties, lower process temperatures, and higher throughput compared to the state-of-the-art fabrication methods and solar cells. Preferred doped layer formation methods use liquid phase epitaxy doping (LPE-D) which enables precise, tunable control over the emitter concentration profile, thus reducing emitter saturation current and leading to improved solar cell efficiency. Preferred methods provide surface dopant concentration that is determined solely by the solubility of the dopant at the eutectic temperature. The high-concentration near-surface dead layer typical of diffused emitters can be reliably circumvented, while maintaining good contacting by alloy eutectic engineering as needed.

Preferred methods can be used to perform either P type or N type doping. Example preferred methods form a replacement of prior boron and/or phosphorus solid state and gas diffusion process. The doping methods of the invention decouple emitter formation from the slow solid-state kinetics of gas diffusion. With methods of the invention, the doping profile formed is largely time-independent and can proceed very quickly—theoretically, doping could be done in a brief firing step in several seconds or during bulk impurity gettering for 10-60 minutes, allowing throughput to be optimized without constraining cell architecture in next generation solar cells. The present methods' liquid phase epitaxy approach results in a nearly uniform doping concentration profile that can provide significantly lower saturation currents and improved surface passivation in comparison to existing and proposed industrial diffused emitters.

In a preferred method, highly-doped layers in solar cells are formed via liquid phase epitaxy doping (LPE-D). Initially, for LPE-D, a thin layer 10s nm to microns thick of a “eutectic-former”, a metal or metal alloy that also serves as or includes the dopant is deposited on the Si surface. A preferred thickness of the eutectic former layer is in the range of 10 nm to 3 μm. A practical limit is 10 μm. Multiple dopants could be used if desired, e.g. Al and B are both P-type dopants. The deposition of the eutectic-former layer can be via any suitable deposition processes, such as physical vapor deposition (evaporation/sputtering), electrodeposition, or the simple method of powder deposit. Any technique that deposits the eutectic former/dopant without oxidizing the eutectic former metal or metal alloy can be used. Other eutectic formers and dopants can be used. For P-type emitters, preferred eutectic formers include Sn, Zn and Al, and dopants include B, Ga, and Al, e.g. combinations of preferred P type dopant-metal eutectic formers include B—Sn, Ga—Sn, B—Zn, Ga—Zn, Al—Zn, and B—Al. For N type emitters, preferred eutectic formers include Sn, Zn, Bi and dopants include P and Sb, e.g., combinations of preferred N type dopant-metal eutectic formers include P—Sn, Sb—Zn, P—Zn, P—Al and P—Bi. Generally, the eutectic-former should have a low silicon eutectic temperature (e.g., <650°, more preferably <600°) and preferably a lower solubility in silicon compared to the dopant included in the material. Al represents a unique example that serves both as the eutectic former and the dopant, and will perform similarly to other combinations above to form a p-n junction though there is no difference in solubility. Methods of the invention permit co-optimization of dopant profile and gettering. Table 1 shows eutectic temperatures for example preferred metals that can be used as the eutectic formers:

TABLE 1
Low-temperature Eutectic-Forming Elements in Silicon

| Element | Eutectic Temperature in Si (° C.) |
|---|---|
| Sb | 630 |
| Al | 577 |
| Zn | 420 |
| Au | 363 |
| Bi | 271 |
| Sn | 232 |

The eutectic-former with dopant is deposited upon a silicon substrate, such as an Si wafer or bulk Si. Upon heating past the system eutectic temperature, the eutectic-former layer and a portion of the Si melts and the eutectic-former layer incorporates some of the Si near-surface as it forms a liquid eutectic. When cooling begins from the peak annealing temperature, the eutectic melt supersaturates with Si. With fast diffusion kinetics in the liquid layer, the Si recrystallizes on the wafer surface epitaxially, saturated with the eutectic-former—and any additional dopants—at a concentration equal to their solid solubilities in silicon at the temperature where that layer of Si epitaxially recrystallizes. Finally, when cooled to the eutectic temperature, the remaining melt solidifies completely at the eutectic composition. A single etch with HCl (or HF) can remove the solidified metallic eutectic layer with the doped Si itself serving as an etch stop. Phosphorus as an example dopant can produce an emitter that would result in an emitter saturation current density lower than that of most conventional diffused emitters (<50 fA/cm̂2).

Preferred methods permit the surface concentration to be fine-tuned by changing the eutectic-former and/or engineering a ternary eutectic temperature to ensure good contacting, e.g. via mixed-metal alloying (such as alloys of the examples above, e.g., e.g. Pb/Sn) that commonly lowers the system eutectic in Si. Surface doping concentration and surface passivation are nearly perfectly correlated. The depth of the doped emitter that is formed can be arbitrarily adjusted by changing the initial thickness of the eutectic-former layer. Thicker emitters are strongly protected from shunts. The peak doping concentration at the deepest part of the emitter can be controlled by changing the peak process temperature without changing the depth of the emitter by adjusting the eutectic-former loading (thickness) accordingly. A thicker layer provides more metal and the melt becomes richer with silicon at higher temperatures. Generally, this provides two variables that can be controlled to engineer the junction that is formed, as further detailed in Equation (1) below. The thickness of the eutectic former (gₘ) and the peak temperature (Tₚ) determine the thickness of the emitter (W). The peak temperature controls richness of the eutectic melt by determining the weight % of Si in the eutectic phase, which increases with temperature.

Preferred methods of the invention can be applied, for example, as an extension and improvement of the aluminum-silicon eutectic formation of the back-surface field and planar back contact of most of today's silicon solar cells that is discussed above in the background. Methods of the invention provide compositions and dopant compensation designed for the front surface and n-type doping. Surface and film properties during the melting reaction determine the morphology and uniformity of the recrystallized layer, and are applied toward junction formation to create silicon based photovoltaics. Methods of the invention provide liquid-phase epitaxy doping to tailor emitter profiles broadly for N and P types emitters, and can be engineered by selection of one or more dopant elements for a given eutectic temperature. Compared to solid-state diffusion, liquid phase epitaxy doping (LPE-D) is fundamentally different in the mechanism of how dopants are transported into the Si lattice.

Preferred methods provide many manufacturing advantages compared to prior solid-state diffusion and gas diffusion methods. Preferred methods are carried out at lower temperatures using eutectic melting and subsequent regrowth of the near-surface Si to incorporate the dopant, lowering equipment and process cost and preserving bulk lifetime. The emitter doping process can be shortened to several seconds. For an example solvent-dopant of Al-BSF (Back Surface Field—the process discussed in the background for back surface contact formation—which creates the heavily doped P-type layer, which in operation creates an electric field known as the Back Surface Field), the liquid film forms almost instantaneously when heating above the eutectic. Because lower process temperatures can be used, the doping profile is largely invariant with process time. Even with relatively high-temperature Sb as the eutectic former (T˜650° C.), dopants like P do not have the thermal energy required to overcome the significant diffusion activation energies that demand the higher temperatures of current processes (>800° C.). The dopant profile is thus largely fixed during re-solidification of the eutectic with little further solid-state diffusion. If beneficial, extended segregation gettering (e.g., 30 min at 600° C.) can be performed without affecting the final emitter profile. Segregation gettering has high segregation coefficients even at peak process temperature. One-sided local N- or P-type doping provides facile incorporation into advanced architectures. Printing of selective emitters can be achieved by varying thickness of the eutectic-former layer in a single step. All back-contact devices can use liquid phase epitaxy doping for both P- and N-type regions. Compared to prior methods, no net process steps are added. A doped-glass deposition, diffusion, and glass etch are replaced by one-sided evaporation or printing, low temperature annealing, and an etch. Other deposition methods include thermal evaporation, e-beam evaporation, electrodeposition, sputtering and screen-printing, which converts powder into a spreadable paste. Experiments to demonstrate the invention used a form a screen printing, with terpineol employed to create the spreadable paste of a metal/dopant powder. Electrodeposition is a preferred deposition process because it is scalable at low cost.

Preferred embodiments of the invention will now be discussed with respect to the drawings and experiments used to demonstrate the invention. The drawings may include schematic representations, which will be understood by artisans in view of the general knowledge in the art and the description that follows. Features may be exaggerated in the drawings for emphasis, and features may not be to scale.

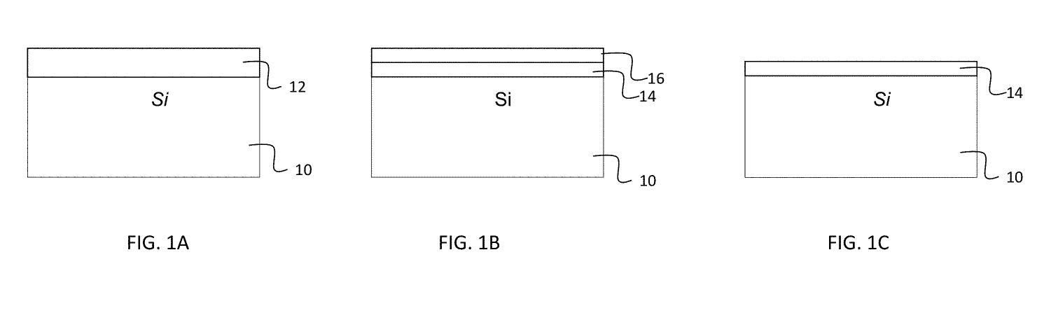

FIGS. 1A-1C illustrate a preferred method for liquid phase epitaxy doping to form a p-n junction in an Si wafer 10 or bulk Si. A metal solvent eutectic-former layer 12 of 0.1-100s of microns thick is deposited onto the silicon surface. Example methods include depositing powders of solvent and dopant (as in experiments below) and solid-state alloying or by (electro)chemical deposition of dopant precursors on eutectic-forming metal films (e.g., phosphoric acid or phosphates deposited on Zn evaporated layers). Prior to evaporation onto wafer substrates, a standard RCA wafer cleaning can be performed to clean the surfaces. Emitter formation can be carried out initially in a forming gas furnace atmosphere to prevent oxidation.

The eutectic-former layer 12 includes a P or N type dopant. Upon heating past the solvent-silicon eutectic temperature, the metallic solvent layer melts and incorporates the near-surface Si as an eutectic composition layer forms. Until the peak annealing temperature is reached, more and more silicon is consumed, following the liquidus curve of the phase diagram in equilibrium. The silicon substrate 10 serves as an infinite source for silicon atoms during the heating process. As cooling from the peak temperature ensues, the eutectic melt becomes supersaturated with Si. The Si recrystallizes epitaxially onto the wafer surface and is saturated with any dopants at a concentration equal to their solid solubilities in Si at the temperature at which recrystallization occurs to form a doped emitter layer 14. Once cooled below the eutectic temperature, the remaining melt solidifies completely at the eutectic composition to form a solidified metallic eutectic layer 16 that is alloyed with silicon from the silicon substrate 10. To remove the solidified metallic eutectic layer, a single etch with a strong acid such as HCl (or HF) can be used with the Si itself serving as an etch stop to remove the metallic eutectic layer 16, leaving the doped emitter layer 14 that forms a uniform and abrupt p-n junction with the silicon 14.

The formed doped emitter layer and the p-n junction can be engineered. Eq. (1) can be used to calculate the width of the doped layer for a given solvent loading, g_{M} [See, J. del Alamo, J. Eguren and A. Luque, “Operating Limits of Al-Alloyed High-Low Junctions for BSF Solar Cells,” Solid-State Electronics 24, pp. 415-420, 1981]. The depth of the emitter, Wₑₘᵢₜₜₑᵣ, is determined entirely by the binary phase diagram: by the amount of Si incorporated into the melt at the peak temperature, wt %_{Si}^{T}^{ₚ}, and after re-solidification, wt %_{Si}^{T}^{ₑᵤ}.

$${W}_{emitter} = \frac{{g}_{M}}{{ρ}_{si}} ( \frac{wt {\%}_{Si}^{{T}_{p}}}{100 - wt {\%}_{Si}^{{T}_{p}}} - \frac{wt {\%}_{Si}^{{T}_{eu}}}{100 - wt {\%}_{Si}^{{T}_{eu}}} ) \qquad ( 1 )$$

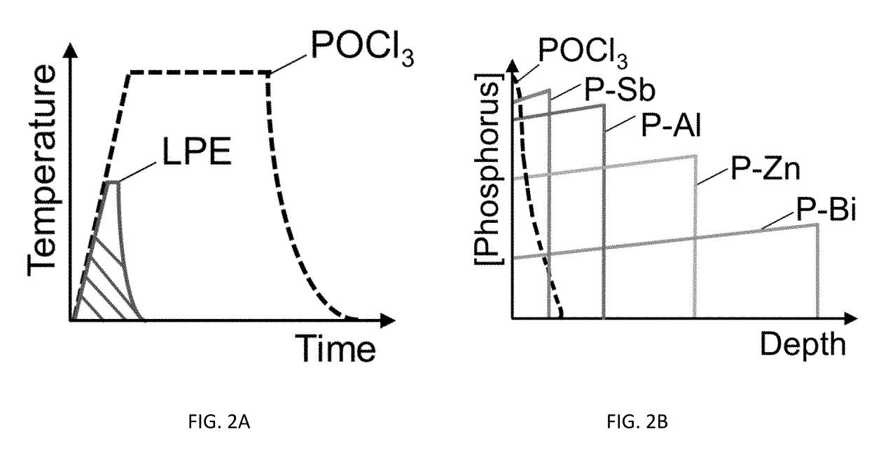

As shown in Eq. 1, for a given loading (thickness) of the eutectic-former, g_{M}, the depth of the final emitter, Wₑₘᵢₜₜₑᵣ, is determined by how much Si is incorporated in the eutectic melt at the peak temperature, wt %_{Si}^{T}^{ₚ}, and ρₛᵢ is the density of silicon after resolidification at the eutectic temperature, wt %_{Si}^{T}^{ₑᵤ}. The resulting diffusion profiles are thermodynamically deterministic, rather than kinetically-controlled. Extensive simulations indicate the value-added by replacing tube diffusions with liquid phase epitaxy doping (LPE-D). The LPE-D process can reduce the emitter saturation current, leading to improved solar cell efficiency, by enabling precise, tunable control over the emitter concentration profile. The present methods can increase manufacturability and drive down the levelized cost of solar energy by cutting the process temperature in half and the process time by 100×. Experimental demonstration showed that the p-type emitters, B and Al, are suitable dopants, and can replace the BBr₃ diffusion process required currently for n-type cell processes. FIG. 2A illustrates that the present LPE method uses a fraction of the thermal budget and a small fraction of the time required for POCl₃ solid state diffusion. FIG. 2B compares the gradual “tail” concentration of phosphorous concentration produced as a function of depth for the prior POCl₃ diffusion, compared to the engineered and abrupt doping profiles that can be produced via the present invention.

The shape of the dopant profile is determined thermodynamically in liquid phase epitaxy, rather than kinetically as in solid state diffusion. This difference stems from the rapid diffusion in the liquid melt layer, which homogenizes the dopant and keeps the system in equilibrium at reasonable cooling rates of even 10s ° C./min. Doping profiles can be tuned flexibly throughout the concentration profile design space by changing solvent load and peak temperature.

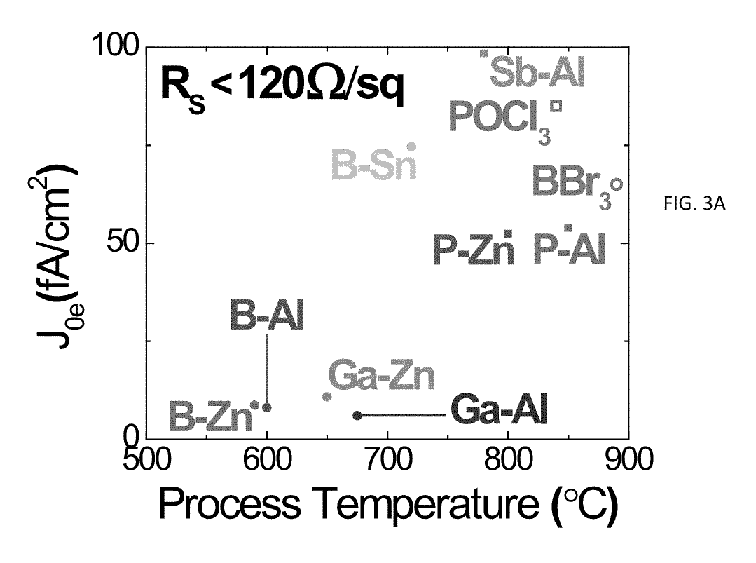

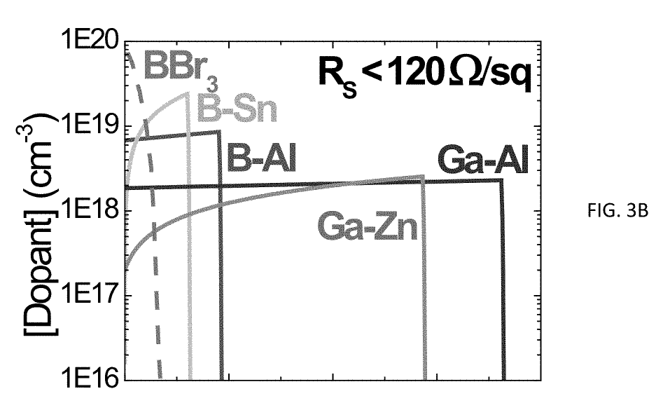

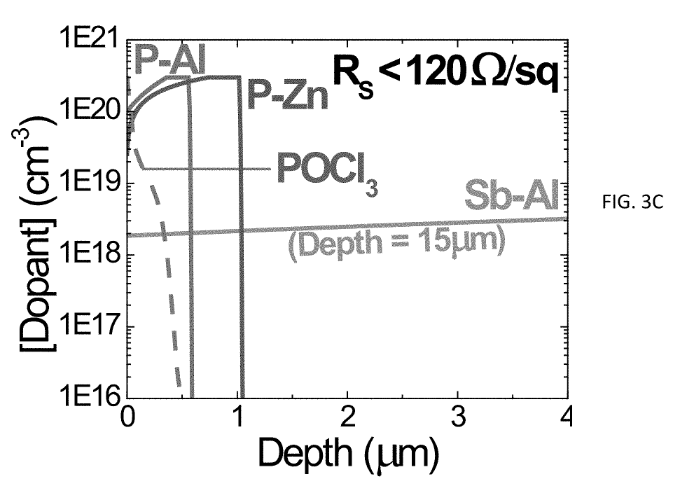

Cmd-PClD simulated emitter saturation current densities, J₀ₑ, for attractive n- and p-type dopant-solvent systems for the present LPE-D methods are shown as a function of process temperature in FIG. 3A compared to POCl₃ and BBr₃. All profiles shown have a contactable sheet resistance below 120 Ω/sq. J₀ₑ values for conventional BBr₃- and POCl₃-diffused emitters are also shown (top right). In comparison, emitters with J₀ₑ as low as 7 fA/cm² are produced with present LPE-D emitters. The corresponding emitter doping profiles calculated based on Eq. 1 are shown in FIG. 3B for P-type and FIG. 3C for N-type emitters. Each simulated process was carried out such that the emitter saturation current densities are minimized while maintaining a sheet resistance <120 Ω/sq. Each metal solvent selected—Al, Zn, and Sn—has a favorable eutectic temperature within the Si binary system (Tₑᵤ=577, 420, and 232° C., respectively), well below typical gas-diffusion temperatures used (850-1000° C.). FIGS. 2B and 3B-3C show that doping profiles of the invention can be uniform with depth and exhibit an abrupt junction, which can offer a V_{OC} (Open Circuit Voltage) entitlement, which is a critical parameter for operating efficiency of a solar cell. The depth can also be tuned to be many microns deep. In the example of P doping from an Al eutectic (P—Al), Al will be incorporated as a compensating p-type dopant, but compensation throughout the emitter profile is 1% or less (N_{D}/N_{A}>100). Due to the slight retrograde solubility of most impurities in silicon, the concentration of eutectic-former and the dopant decreases slightly toward the surface in correspondence with the temperature decrease during cooling down to resolidification.

The present methods allow for substantial tunability, as the depth and peak dopant concentration can be tuned independently (using solvent load and peak process temperature, respectively). The LPE-D approach also requires significantly less time than a typical tube diffusion (POCl₃ chemical vapor deposition and diffusion), as the liquid forms almost immediately after heating above the eutectic. A reduction in processing temperature and duration translates to lower equipment and thermal processing costs.

FIGS. 3A and B provide guidance regarding the flexibility that is provided by the invention and the ability of the invention to provide engineered emitter layers and p-n junctions in solar cells with deep and abrupt doping profiles. A typical phosphorus tube diffusion will result in an emitter with a surface concentration between 5×10¹⁹ and 1×10²¹ atoms/cm⁻³ in a characteristic kink-and-tail profile shown as dashed line in FIGS. 3A and 3B. The high-concentration plateau extends typically 50-60 nm deep followed by a drop with a deeper, lower concentration tail exhibiting a sloping decrease to 1×10¹⁶ extending 300-500 nm into the bulk of the silicon, until it falls below the background doping level at the p-n junction. In contrast, the present methods allow tailoring of the surface concentration, for example between 1×10¹⁷ and 3×10²⁰ atoms/cm⁻³ depending on the dopant selected. The dopant penetrates an arbitrary depth into the bulk, depending upon the loading of the eutectic former and the peak temperature of the process, with a wide range between narrow (100 nm or less) to very deep (even 10s of microns), with preferred junctions being 100 to tens of microns deep, or 500 nm to 10 microns deep, with other preferred junctions being 300 nm to 3 micron deep, and others being 3-10 microns deep, all of which are made possible by the invention.

The doping profile produced by methods of the invention can be flat or retrograde in character—where the dopant profile decreases from the bulk to the surface, which is opposite classical diffusion profiles that have a profile that increases substantially from the bulk to the surface with the highest concentration being at the surface of the emitter. With the present formation methods, the peak concentration of dopant occurs at the deepest point in the profile and is determined by the solid solubility of the dopant at the peak temperature. The surface concentration is determined by the solid solubility of the dopant at the eutectic temperature of the alloy.

With methods of the invention, to achieve a particular depth of the emitter, either the eutectic former loading or the peak temperature can be changed. Increasing the eutectic former loading at constant peak temperature effectively stretches the shape of the doping profile while keeping both the surface and peak concentrations the same. Alternatively, the degree of retrograde character in the present doping profile can be tuned by changing the peak temperature while keep eutectic former loading constant, which increases the retrograde character as the peak concentration increases at the deepest point. Thus, increasing the metal loading while minimizing the excursion in temperature above the eutectic will minimize the retrograde character and keep the dopant profile flat. Because the present process can be executed within seconds or minutes, there is little solid-state diffusion that occurs to soften the abruptness of the profile. At the furthest extent (depth) of doping into the bulk, there is an abrupt drop within 1-100 nm of up to four orders of magnitude in concentration until the doping is below the background dopant level within a span of tens of nanometers

If useful, extended segregation gettering can be performed without affecting the final emitter profile substantially. Segregation gettering to the liquid eutectic layer can provide a higher segregation coefficient than phosphorus gettering. One-sided local n- or p-type doping can also be achieved, providing facile incorporation into advanced architectures, such as selective emitters or back contact devices.

### Experiments

Experiments were conducted using B and Al powders as dopants and Al powder as the eutectic solvent (including Al—Al as former-dopant). A paste containing the powders was doctor bladed on the Si wafers depending upon the desired final thickness by adjusting the loading of the solvent applied, gM in Eq. (1). To prevent dewetting of the nanometric liquid film, a thin capping/wetting layer of spin on glass (SOG) was applied atop the paste. A typical experiment spin coated glass as a capping layer on top of a thin paste of the eutectic former/dopant, which may otherwise dewett due to its thinness.

Eutectic melting was confirmed to occur by differential scanning calorimetry. Other options for preventing dewetting include conventional thin film approaches. For example, preparation of the silicon surface prior to deposition to alter surface hydrophobicity can be used maintain wetting. In addition, a thin capping oxide can be used maintain the intended wetting. After annealing, the wafer was etched in 1% (vol) HF for 5 minutes and pure HCl for 20 minutes to get removed the glass and excess solidified eutectic melt. Four-point probe was used to measure the sheet resistance of the annealed Si wafers and their n/p type nature of the emitter layer was confirmed with the hot point probe method. Surface topography was analyzed via SEM and elemental mapping was performed via EDX. Other experiments were conducted using B powder and a sputtered Sn layer that was limited to 4.5 μm thick by equipment constraints as the dopant and solvent, respectively.

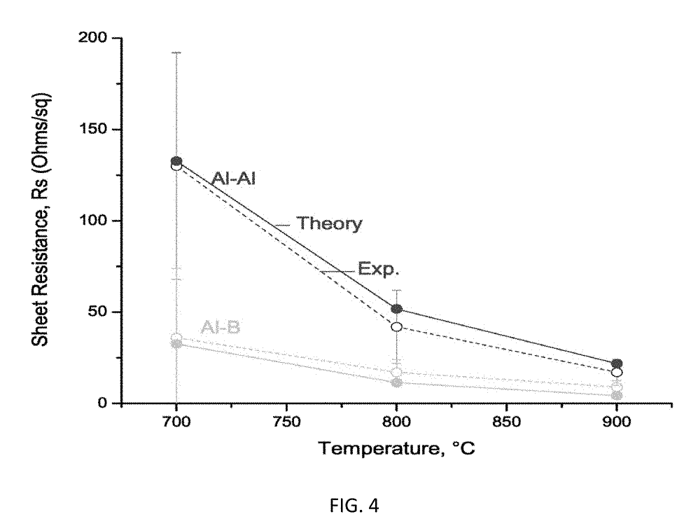

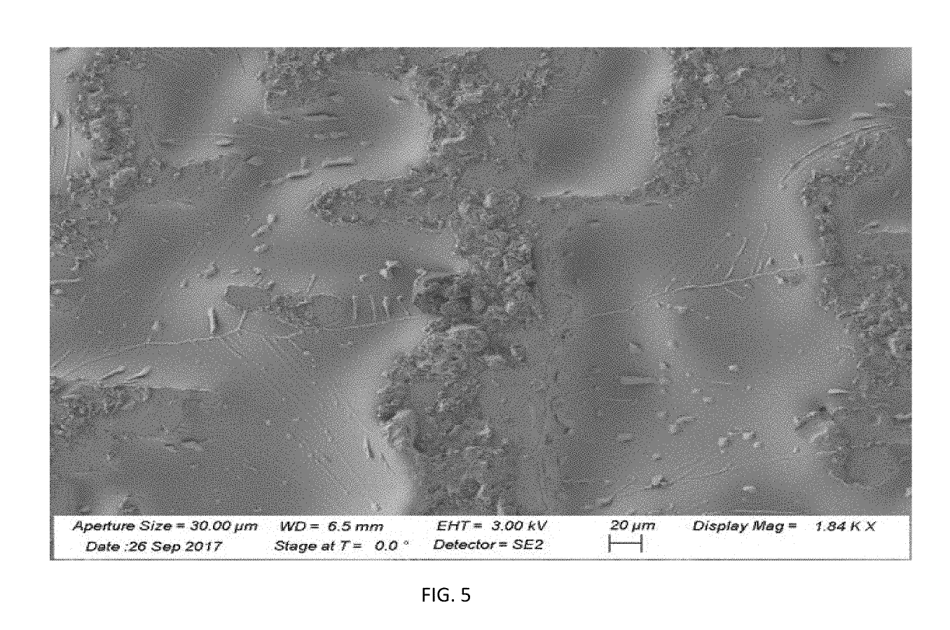

Sheet resistance as a function of annealing temperature was determined and is shown in FIG. 4 compared to the theoretical predictions of Eq. (1). Good agreement between the Rₛ obtained via the experimental method and the simulated values is obtained.

After etching removes the eutectic layer, wafers with Al—B emitters that are nominally 4.9 μm deep show a wavy topography on their surface as can be seen in FIG. 5. The wavy topography can be controlled to a degree by changing the thickness of the emitter. When the eutectic layer melt is formed, the pyramids that form the texture of the silicon wafer also melt. Typically, such pyramids are 10 μm tall. An eutectic melt that melts 4.9 μm deep of the silicon wafer results in waviness. With a 1 μm melt, then a pyramidal texture is retained, but the peaks are rounded. Sharp peaks are detrimental to the final device, so rounding is definitely advantageous to solar cell operation and is provided by preferred methods of the invention. On the other hand, total loss of texture is not desirable. Some texture on the front of a solar cell is advantageous for anti-reflection. Depending on the initial texture of the wafer and the depth of the emitter desired, the reflectance of the front/back surface can be tuned.

While specific embodiments of the present invention have been shown and described, it should be understood that other modifications, substitutions and alternatives are apparent to one of ordinary skill in the art. Such modifications, substitutions and alternatives can be made without departing from the spirit and scope of the invention, which should be determined from the appended claims.

Various features of the invention are set forth in the appended claims.

1. A method for forming a doped silicon layer or a silicon alloy, the method comprising providing a silicon substrate having a silicon surface, depositing an eutectic-former layer with dopant on the silicon surface, heating past a system eutectic temperature of the eutectic-former layer and silicon to form a liquid eutectic melt that incorporates some of the silicon near-surface into the liquid eutectic melt, and cooling to supersaturate the liquid eutectic melt with silicon and recrystallize silicon doped with the dopant.

2. The method of claim 1, further comprising continuing cooling to the system eutectic temperature to solidify remaining liquid eutectic melt.

3. The method of claim 2, further comprising etching to remove non-alloyed or non-doped solidified metallic eutectic layer

4. The method of claim 3, wherein silicon doped with the dopant serves as an etch stop during said etching.

5. The method of claim 2, wherein said depositing further comprises dewetting prevention.

6. The method of claim 5, wherein said dewetting prevention comprises altering surface hydrophobicity of the silicon surface.

7. The method of claim 5, wherein said dewetting prevention comprises depositing a thin oxide or glass on the eutectic-former layer.

8. The method of claim 1, wherein the eutectic forming layer consists of one of Al, Sb, Bi, Zn, and Sn and the dopant.

9. The method of claim 9, for forming an N-type emitter, wherein the dopant is one of P and Sb and the eutectic former is one of Sn, Zn, and Bi.

10. The method of claim 9, for forming a P-type emitter, wherein the dopant is one of B, Ga, and Al and the eutectic former is one of Sn, Zn and Al.

11. The method of claim 1, wherein the eutectic former has a lower solubility in silicon than the dopant.

12. The method of claim 11, wherein the eutectic former layer with dopant is in the range of 10 nm to 3 μm thick.

13. The method of claim 11, wherein the eutectic former comprises a metal.

14. The method of claim 11, wherein the eutectic former comprises a mixed metal alloy.

15. The method of claim 1, wherein the depositing comprises depositing powder of the eutectic former and the dopant.

16. The method of claim 1, wherein the deposition comprises evaporation or printing.

17. The method of claim 1, wherein said depositing is controlled to set a predetermined doping depth determined by a phase diagram of the eutectic system of the eutectic former and silicon.

18. A silicon solar cell, comprising a silicon substrate, an emitter layer within the silicon substrate, a p-n junction defined by a junction of the emitter layer with the remaining silicon substrate, wherein the emitter comprises a doping profile with a doping concentration at the p-n junction that is equal or greater than the doping concentration at a surface of the emitter layer.

19. The silicon solar cell of claim 18, wherein the p-n junction is 100 nm to tens of microns deep.

20. The silicon solar cell of claim 19, wherein the p-n junction is 500 nm to 10 microns deep.

21. The silicon solar cell of claim 18, wherein the dopant concentration at the p-n junction transitions from a maximum doping concentration at the p-n junction to a background doping concentration within 1-100 nm of depth.

22. A method for forming a doped silicon layer or a silicon alloy, the method comprising providing a silicon substrate having a silicon surface, depositing an eutectic-former Al layer on the silicon surface, capping the Al layer for dewetting prevention, heating past a system eutectic temperature of the eutectic-former layer and silicon to form a liquid eutectic melt that incorporates some of the silicon near-surface into the liquid eutectic melt, and cooling to supersaturate the liquid eutectic melt with silicon and recrystallize silicon doped with Al dopant.
